(19) United States
(12) Patent Application Publication
(10) Pub. No.: US 2025/0299995 A1
(43) Pub. Date: Sep. 25, 2025

(54) Roughened Carrier for Debonding of Bonded Stack

(71) Applicant: PulseForge, Inc., Austin, TX (US)

(72) Inventors: Ian M. Rawson, Austin, TX (US); Harry Chou, Austin, TX (US); Kurt A. Schroder, Coupland, TX (US); Vahid Akhavan Attar, Austin, TX (US)

(21) Appl. No.: 19/089,850

(22) Filed: Mar. 25, 2025

Related U.S. Application Data
(60) Provisional application No. 63/569,712, filed on Mar. 25, 2024.
(60) Provisional application No. 63/766,681, filed on Mar. 4, 2025.

(51) Int. Cl. H01L 21/683; C09J 5/06; H01L 21/304; H01L 21/67; H01L 23/00

(52) U.S. Cl. CPC H01L 21/6835; C09J 5/06; H01L 21/304; H01L 21/67115; H01L 24/83; C09J 2203/326; H01L 2221/68318; H01L 2221/68381; H01L 2224/83005; H01L 2924/351

(57) ABSTRACT

Temporary electronics carrier structures and associated systems and methods. A carrier structure for temporarily carrying an electronics structure to be debonded from the carrier structure. The carrier structure includes a roughened surface that has an average surface roughness between about 50 nm and about 5 microns. A temporarily bonded stack includes the carrier structure, an electronics structure, and a temporary adhesive located between the carrier structure and the electronics structure. A system for debonding the temporarily bonded stack includes a light source configured to emit light into the carrier structure toward a roughened face thereof.

### CROSS-REFERENCE TO RELATED APPLICATIONS

This application claims the benefit of U.S. Provisional Application No. 63/569,712, filed Mar. 25, 2024 and U.S. Provisional Application No. 63/766,681, filed Mar. 4, 2025, each of which is hereby incorporated herein by reference in its entirety.

### FIELD

The present disclosure generally relates to electronics device manufacturing, and more particularly equipment and methods that involve temporarily bonding an electronics device to a carrier for processing.

### BACKGROUND

This disclosure is directed to equipment and methods for temporary bonding and debonding (TBDB), which can be employed to affix fragile materials to a maneuverable carrier to facilitate the processing of electronics structures such as electronics devices (e.g., small-scale electronics components, such as epoxy molding compound packaging, integrated circuit packaging, power or MOS devices, multijunction or tandem solar cells, two-dimensional materials, battery materials, and, more broadly, wafers and panels) in manufacturing settings.

### SUMMARY

In one aspect, a reusable carrier structure is for temporarily carrying electronics structures to be debonded from the carrier structure by flashlamp illumination in photonic debonding. The reusable carrier structure comprises an electronics structure carrier configured to temporarily carry the electronics structures in multiple temporary bond-debond use cycles of the electronics structure carrier. The electronics structure carrier comprises a first light-receiving face and a second face. The light-receiving face is configured for receiving light from the flashlamp illumination. The second face is located generally opposite the first light-receiving face. The second face comprises a roughened surface. The electronics structure carrier comprises a carrier body configured to permit transmission of light from the flashlamp illumination via the first light-receiving face to pass through the carrier body toward the second face. The roughened surface of the second face has an average surface roughness between about 50 nm and about 5 microns to facilitate photonic debonding of the electronics structures from the electronics structure carrier.

In another aspect, a method of producing a carrier structure for temporarily carrying an electronics structure to be debonded from the carrier structure by photonic debonding includes providing a roughened surface on a carrier body and placing a light-absorbing layer on the carrier body. The roughened surface has an average surface roughness between about 50 nm and about 5 microns. The light-absorbing layer comprises a carrier-body-facing surface and a bonding surface located opposite the carrier-body-facing surface. The bonding surface has an average surface roughness between about 50 nm and about 5 microns.

In yet another aspect, there is a method of using a carrier structure having one or more roughened surfaces for processing electronics structures comprising several steps. A temporary stack is formed. The temporary stack comprises the carrier structure, a first electronics structure to be processed, and a temporary adhesive disposed between the carrier structure and the first electronics structure. The carrier structure comprises a roughened surface having an average surface roughness between about 50 nm and about 5 microns. The roughened surface of the carrier structure faces toward the temporary adhesive. Then, the electronics structure is processed while the electronics structure is temporarily bonded to the carrier structure. Then, one or more pulses of light are emitted from a light source such that the light is transmitted into the carrier structure toward the roughened surface to generate heat at a boundary between the carrier structure and the temporary adhesive to loosen the electronics structure with respect to the carrier structure. Then, the processed electronics structure is separated from the carrier structure.

Other objects and features will be in part apparent and in part pointed out hereinafter.

### BRIEF DESCRIPTION OF THE DRAWINGS

FIG. 1A is a diagram of a carrier structure with non-roughened surfaces according to one embodiment of the present disclosure;

FIG. 1B is a diagram of a bonded stack comprising the carrier structure shown in FIG. 1A, an electronics structure, and a temporary adhesive between the carrier structure and the electronics structure;

FIGS. 2A and 2B are diagrams depicting a method of debonding the bonded stack shown in FIG. 1B using a flash lamp as a light source;

FIGS. 3A-3B are diagrams depicting a method of debonding a bonded stack comprising a carrier structure with non-roughened surfaces, an electronics structure, and a temporary adhesive between the carrier structure and the electronics structure using a laser as a light source according to another embodiment of the present disclosure;

FIG. 4 is a diagram of another carrier structure that includes a carrier body with a roughened surface and a light-absorbing layer with roughened surfaces, one of the roughened surfaces of the light-absorbing layer facing the roughened surface of the carrier body;

FIG. 5 is a diagram of yet another carrier structure that includes a carrier body with non-roughened surfaces and a light-absorbing layer with a non-roughened surface facing the carrier body and a roughened surface opposite the non-roughened surface;

FIG. 6 is a diagram of yet another carrier structure that includes a carrier body with a non-roughened surface and a roughened surface and a light-absorbing layer with a roughened surface facing the roughened surface of the carrier body and an opposite non-roughened surface;

FIG. 7A is a diagram of a bonded stack comprising the carrier structure shown in FIG. 4, an electronics structure, and a temporary adhesive between the carrier structure and the electronics structure;

FIGS. 7B and 7C are diagrams depicting a method of debonding the bonded stack shown in FIG. 7A using a flash lamp as a light source;

FIG. 8 is a fragmentary diagram depicting a manifold between a portion of the light-absorbing layer and a portion of the adhesive as a result of the method shown in FIGS. 7B and 7C;

FIG. 9A is a diagram of another bonded stack comprising a carrier structure that includes a carrier body with a roughened surface, an electronics structure, and a temporary adhesive between the electronics structure and the roughened surface of the carrier body;

FIGS. 9B and 9C are diagrams depicting a method of debonding the bonded stack shown in FIG. 9A using a laser as a light source;

FIG. 10 is a diagram depicting an alternative method of debonding the bonded stack shown in FIG. 9A using a flash lamp as the light source;

FIG. 11 is a diagram depicting a bonded stack comprising a carrier structure including a carrier body with two roughened surfaces and a light-absorbing layer with two roughened surfaces, an electronics structure, and a temporary adhesive between the electronics structure and the light-absorbing layer, with representations of incident light beams directed into the carrier body and toward the light-absorbing layer;

FIG. 12 is a diagram depicting another bonded stack comprising a carrier structure including a carrier body with two roughened surfaces, a light-absorbing layer with two roughened surfaces, and a supplemental layer located between the carrier body and the light-absorbing layer; an electronics structure; and a temporary adhesive between the electronics structure and the light-absorbing layer, with representations of incident light beams directed into the carrier body and toward the light-absorbing layer;

FIG. 13 is a diagram depicting yet another bonded stack comprising a carrier structure including a carrier body with two roughened surfaces, a light-absorbing layer with two roughened surfaces, a first supplemental layer located between the carrier body and the light-absorbing layer, and a second supplemental layer located adjacent the carrier body opposite the first supplemental layer; an electronics structure; and a temporary adhesive between the electronics structure and the light-absorbing layer, with representations of incident light beams directed into the carrier body and toward the light-absorbing layer; and

FIG. 14 is a block diagram of a system for debonding an electronics structure temporarily bonded to a carrier according to one embodiment.

Corresponding reference characters indicate corresponding parts throughout the drawings.

### DETAILED DESCRIPTION

The present disclosure relates to varieties of carriers (broadly, “carrier structures”) used in TBDB and a bonded stack that includes such a carrier that carries an electronics structure so processing operations can be performed while the electronics structure is temporarily carried by the carrier. In the TBDB process, an adhesive is typically used to temporarily secure a functional material (e.g., electronics structure) to a carrier (e.g., a rigid dummy substrate) for processing. After processing, lasers, heat, chemicals, or mechanical methods may be employed to separate the processed device from its respective carrier by damaging an interface between the temporary adhesive and the processed device or between the adhesive and the carrier. In the field of semiconductor wafer debonding, using a flashlamp (e.g., incoherent light source) for such debonding may be referred to as photonic debonding. A debonding process using a laser (e.g., coherent light source) may be referred to as laser debonding.

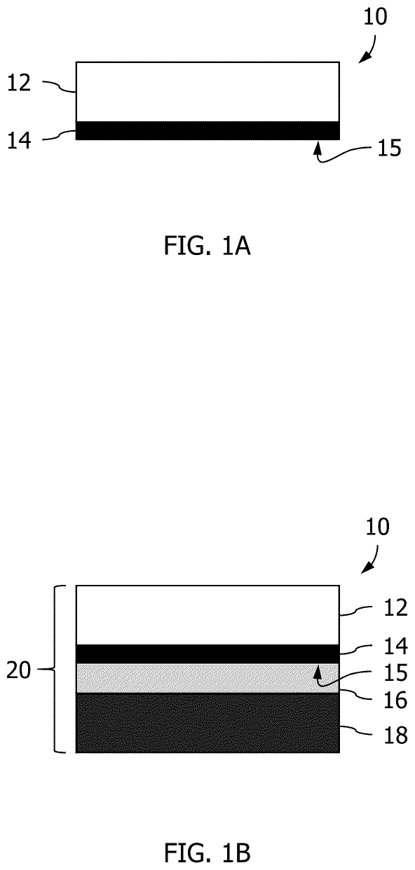

Referring to FIGS. 1A and 1B, one example of a carrier structure (e.g., carrier) suitable for use in TBDB is generally indicated by reference numeral 10. The carrier structure 10 can include a carrier body 12 and a light-absorbing (LA) layer 14 including light-absorbing material (LAM) that is carried on one side of the carrier body (either directly on the carrier body or on another layer and/or material of the carrier structure). The light-absorbing layer 14 can comprise multiple sub-layers and/or materials. The carrier body 12 may comprise a carrier substrate of glass or other suitable material. The carrier structure 10 may optionally include one or more layers (e.g., supplemental layers, such as light-manipulation layers and/or light-refractive layers) or other materials carried by the carrier body 12 (e.g., interlayer in between the carrier body and the LA layer 14 or on an opposite side of the carrier body away from the layer 14). As best shown in FIG. 1B, the carrier structure 10 can be temporarily bonded to a device 18 (broadly, “electronics structure,” such as a semiconductor device wafer) using a temporary adhesive 16 applied to an outer surface 15 of the non-carrier-facing side of the LA layer 14 (bonding face or surface of the carrier) to form a bonded stack 20. The adhesive is cured to secure the carrier to the electronics structure to complete the formation of the bonded stack. The curing process can be a thermal process in which the bonded stack is compressed and heated (thermocompression bonding), or it may be cured by shining ultraviolet (UV) light from the transparent carrier side of the stack. Other methods can be used without departing from the scope of the present disclosure.

After bonding, the electronics structure 18 is processed while the electronics structure is temporarily carried as part of the bonded stack 20. For example, during integrated circuit manufacturing, a thinning step can be performed on a semiconductor wafer having integrated circuits to reduce the thickness of the semiconductor wafer. This could involve thinning of the electronics structure from the backside via grinding, via formation, etc. During processing, the electronics structure 18 may be subjected to mechanical, chemical, and/or thermal stress caused by additional equipment and/or substances. Moreover, processing can include adding electronics components to the device. The carrier structure 10 facilitates the physical and thermal stability of the electronics structure 18 during these processes. After this stage of processing has been completed on the electronics structure 18, and/or other processing functions such as via formation, etc., the processed electronics structure is then detached, e.g., debonded, from the carrier structure so the electronics structure can progress to further stages of manufacturing.

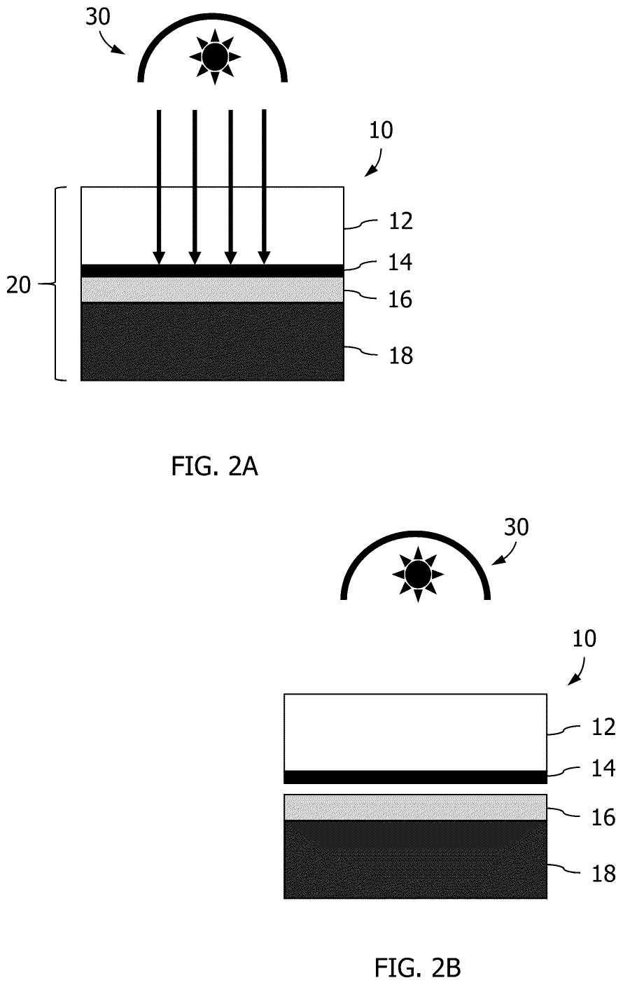

Now referring to FIGS. 2A and 2B, after the electronics structure 18 has been processed, it is removed, or debonded, from the carrier structure 10. This can be accomplished in photonic debonding by using a light source 30 (e.g., a flashlamp guided by a reflector) to irradiate the stack with one or more intense pulses of light, which are emitted from the carrier side (the light-receiving surface or side, as opposed to the side where the electronics structure 18 is carried) and are transmitted through the carrier body 12 and toward the LA layer. A substantial amount of the pulsed light is absorbed by the LA layer 14, which momentarily heats the LAM. The heated LAM causes portions of the adhesive 16 adjacent the outer surface 15 (more broadly, an LA-layer-adhesive interface) to become hotter. The materials at the LA-layer-adhesive interface lose adhesive strength (e.g., due to vaporization of portions of the adhesive material and/or thermal decomposition) when a threshold temperature is reached. It will be appreciated that if the light is to be flashed through the carrier body 12, the carrier body 12 must be at least partially light-transmissive to the frequencies of light to be transmitted to the LA layer 14.

After debonding is completed, the carrier structure 10 and the electronics structure 18 can then be cleaned. The electronics structure 18 then progresses to other processes (e.g., for integration), while the carrier structure 10 can be reused for additional bond/debond cycles with other devices, which can be identical to or non-identical to the electronics structure 18.

One problem with the above-described photonic debonding process can be that a tremendous amount of radiant power is needed to debond an electronics structure, which equates to significant radiant exposure and, more generally, energy, over time. Due to the high energy throughput, the reliability of specialized equipment used for debonding (e.g., flashlamp components and optical elements such as lenses or filters) may be compromised or degraded when used industrially over the course of numerous (e.g., thousands or millions of) flash cycles. For example, flahslamps are prone to decreased efficiency and eventual failure over time, and many optical components are susceptible to solarization, which can render these components less light-transmissive over many uses. As the equipment loses efficiency over many uses, more energy is required to maintain a peak system output, which has the effect of accelerating further wear. Furthermore, some processing operations demand higher-temperature adhesives which require more power from light sources than is practical for existing light source equipment.

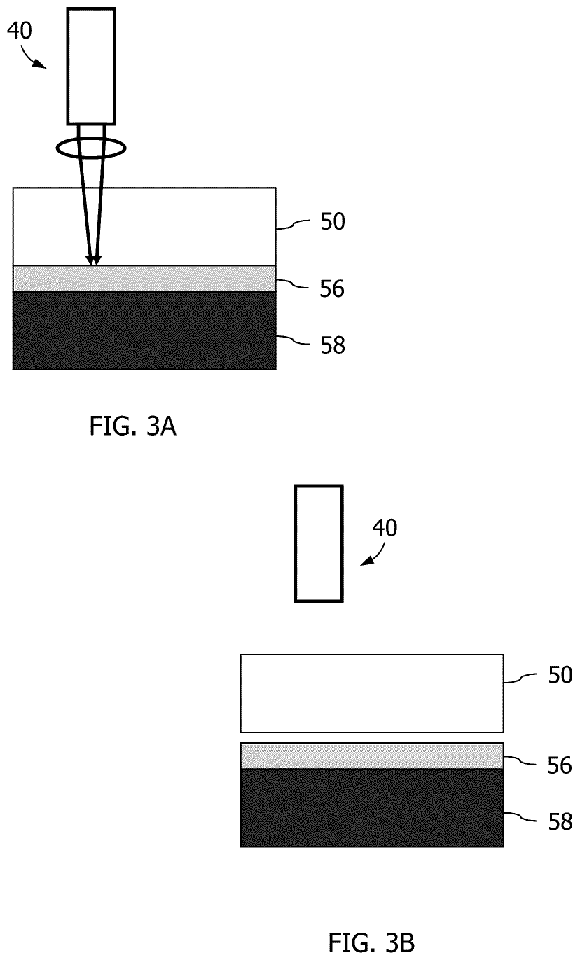

Now referring to FIGS. 3A and 3B, an alternative method to remove electronics structures from a carrier is called laser debonding. In this method, pulsed light from a laser light source 40 is transmitted through a carrier 50 and focused at a carrier-adhesive interface adjacent the outer surface 55 of the carrier to photothermally decompose an adhesive 56 at the carrier/adhesive interface. This reduces the adhesive bond between the carrier 50 and a electronics structure 58 carried by the carrier so they can be separated more readily. The pulsed beam from the laser light source 40 generally has a small beam area, so the laser must be pulsed many times as it is scanned across the back surface of the carrier 50. The pulsed light source may be a UV laser (100 nm to 400 nm wavelength) or near infrared (or NIR) laser (700 nm to 2.5-micron wavelength), so the carrier body 50 is preferably at least partially transmissive with respect to the laser wavelengths being used. The laser beam may be augmented by a beam spreader to increase the width of the beam for faster processing.

Referring generally to FIGS. 2A and 2B again, in cases where light is used to weaken the bonding strength of the adhesives indirectly, e.g., by vaporization or thermal decomposition, increasing the debonding capacity of the LA layer 14 without increasing the power settings on light sources results in desirable system efficiency. For example, this energy efficiency can increase the reliability of the power system for light sources, can reduce stress on the light sources over repeated uses, and can enable lower-energy debonding with bonded stacks having similar shapes and sizes as the above-described bonded stack 20, paving the way for configurations previously viewed as impractical.

LAMs such as the LAM used in LA layer 14 can include metal, metal alloys, dielectrics (e.g., ceramic), semiconductors, and/or high-temperature polymers. Example materials for the LAM include tungsten, tungsten-titanium alloys, and/or amorphous carbon. All of these example materials are thermally stable at high temperatures and have a coefficient of thermal expansion (CTE) that can be matched to suitable carrier body materials (e.g., glass). Having a matching CTE is significant because the temperature reached by the LAM and the adjacent carrier body can reach several hundred degrees C. If the mismatch between the CTEs of the LAM and the carrier body is too large (e.g., when the difference between the CTEs is greater than about 1.5*10⁻⁶/K), the LAM can delaminate from the carrier body during use, or cracks can form, which in either case can render carriers (e.g., carrier structure 10) unusable for repeated processing and debonding cycles. In this regard, costs can be dramatically reduced by designing the carrier to be durable and reusable across numerous (e.g., dozens) of processing and debonding cycles. The present disclosure provides new ways to make the carrier more energy-efficient and/or less susceptible to wear.

Moreover, certain advanced manufacturing processes are tending toward increased processing temperatures to accommodate processes like soldering with lead-free solder or hybrid bonding without any solder at all. In these cases, temporary adhesives must be capable of maintaining their adhesive bond when higher processing temperatures are sustained. As a consequence, higher-temperature adhesives tend to require more energy to debond, which can increase the thermal stress on both the electronics structure and carrier if not controlled.

Disclosed herein are several improved structures and methods to achieve improved debonding processes such as photonic debonding and laser debonding by providing carrier structures with one or more structured surfaces that have a controlled average roughness Ra selected to enhance the debonding capacity of carrier structures so that electronics structures can be more readily released from the carrier structures when debonding operations (e.g., photonic or laser debonding) are performed. As will be apparent from the present disclosure, “roughening” can be broadly understood to encompass both active processes in which a material's or layer's surface or surfaces are altered to introduce roughness and passive processes in which materials are formed with innately rough surfaces. Although surface roughness is primarily described in the present disclosure in terms of amplitude (e.g., the magnitude of vertical deviations relative to an average surface height), it will be appreciated that the frequency (or horizontal magnitude) of surface irregularities can also be controlled in furtherance of the advantages discussed herein without departing from the scope of the present disclosure.

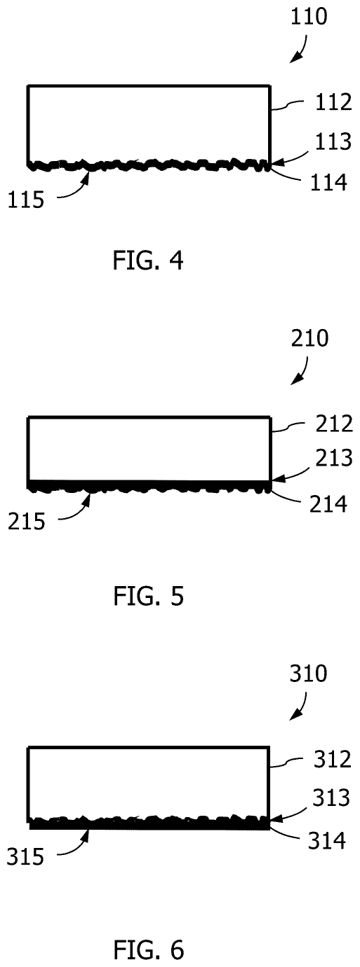

Referring now to FIG. 4, a roughened carrier structure according to one embodiment of the present disclosure is generally indicated by reference numeral 110. As will be described in greater detail below, the roughened carrier structure 110 generally includes a carrier body 112 and a LA layer 114 that are configured to provide a mechanism for increasing the amount of light-induced heating that occurs in the LA layer 114 and that is transferred to materials carried by the carrier structure adjacent an outer surface 115 of the LA layer (the outer LA layer surface). More specifically, in this embodiment, it is contemplated that the LA layer can achieve increased absorption through the addition of surface roughness (e.g., surfaces that are not planar on a scale of several nanometers to several microns) at a boundary 113 between the LA layer 114 and the carrier body 112. It will be appreciated that the boundary 113 is defined by a carrier-body-facing surface of the LA layer and an LA-layer-facing surface of the carrier body. In the present embodiment, both surfaces along the boundary 113 are generally coincident and are therefore understood to have complementary surface roughness characteristics along the boundary 113. In general, when the surfaces have an average surface roughness (“Ra”) in an optimal range (as described below), this structured roughness provides for more light absorption than a substantially smooth surface at this boundary, e.g., where the average surface roughness Ra is less than ˜ 10 nm. Thus, with roughened surfaces at the boundary 113, the light has a greater capacity to be absorbed by the LA layer in comparison to a similar carrier structure with substantially smooth or sub-optimally roughened surfaces that direct less incident light toward the LA layer. Thus, the carrier structure 110 promotes enhanced energy efficiency.

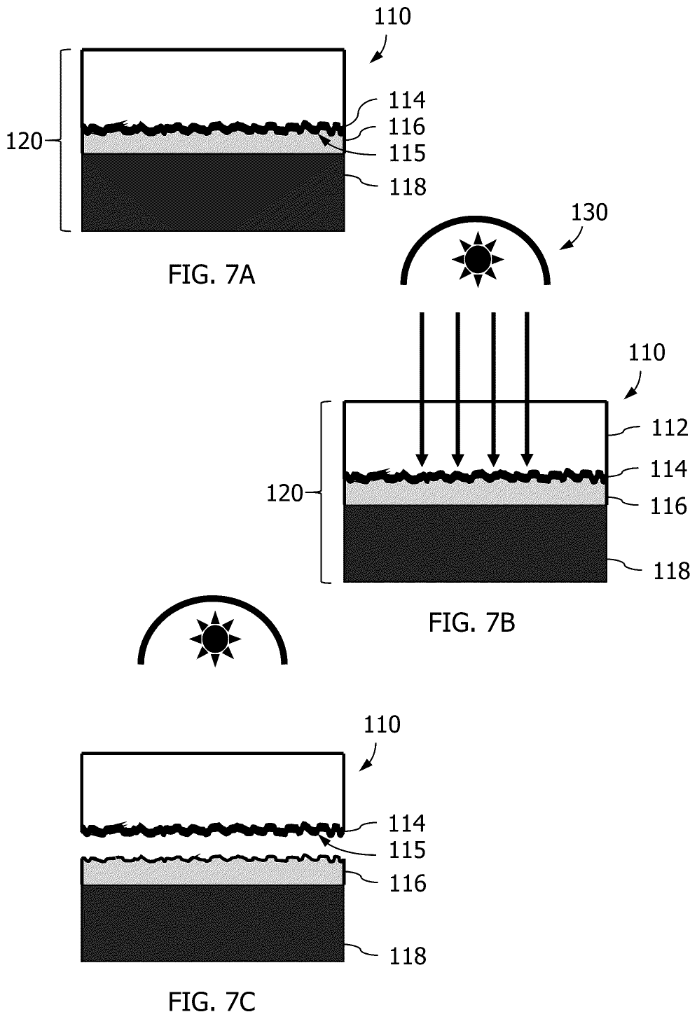

In this manner, controlling the surface roughness of the carrier body 112 and LA layer 114 at the boundary 113 to within an optimized range results in increased light absorptivity in the LA layer compared to surfaces with non-optimized roughness. In effect, this means less light intensity (e.g., radiant exposure in J/cm² and/or radiant power) is needed for the LA layer 114 to cause the adhesive 116 to debond as generally shown in FIGS. 7B-7C (e.g., by reaching a suitable temperature—e.g., around 400° C. for low-temperature polymers or up to around 700° C. for higher-temperature adhesives) or, alternatively, that the overall debonding effectiveness of the LA layer 114 relative to the adhesive 116 (e.g., an operating temperature) can be increased without altering the operating parameters of light sources, etc.

In one aspect, it is contemplated that the average surface roughness Ra of the respective surfaces of carrier body 112 and LA layer 114 along the boundary 113 can be selected to be on the same order of magnitude (or within a factor of 10) as a peak emission wavelength (or multiple peak emission wavelengths) of light being used in the TBDB process. Although the peak emission wavelength is most practically assessed as a function of the discrete wavelength or wavelengths of light emitted by a particular light source (e.g., the light sources 130, 430, 440 discussed below in connection with FIGS. 7B, 9B, 10), it will be appreciated that a “peak wavelength” as described herein can additionally or alternatively be evaluated based on other parameters such as a peak absorptivity of the LA layer 114 to certain light wavelengths (which can be maximized) and/or a peak absorptivity of materials in the carrier body 112 or other adjacent layers to certain light wavelengths (which can be minimized).

As an example, the flashlamp spectrum typically used in photonic debonding is broadband, with wavelengths ranging from about 200 nm up to about 1500 nm, and with a peak emission between wavelengths of about 400 nm and about 600 nm. The average surface roughness Ra of the respective surfaces of the carrier body 112 and/or the LA layer 114 along the boundary 113 can be up to about 600 nm for most efficient use with typical photonic debonding equipment. Of course, other roughness values can be selected for compatibility with other light sources based on different light wavelength values (e.g., up to about a characteristic wavelength of each respective light source).

Notably, when the average surface roughness Ra is greater than the wavelength of the light impinging on it, significant portions of impinging light that are reflected at this boundary are capable of multiple small-scale reflections on the surface. Thus, the impinging light is reflected more times in relatively large cavities and has more opportunities to be absorbed (as opposed to being reflected generally away from the LA layer 114 in an opposite direction). However, even when the average surface roughness Ra is approximately equal to or less than a wavelength of the light coming from the light source, there is still some enhanced absorption of the impinging light due to less predictable light manipulation that occurs on this scale. Accordingly, even though the carrier structure 110 generally exhibits diffuse reflectivity (e.g., nearly perfect Lambertian reflectivity) when the surface roughness at the boundary 113 is less than or approximately equal to the wavelength of light, the effectiveness of debonding is increased. Thus, when the average surface roughness is generally on the scale of the peak wavelength (e.g., less than or approximately equal to the peak emission wavelength of light directed to the surface), a comparatively large amount of the impinging light is directed through the roughened boundary 113 and is absorbed. It will be appreciated that the surface roughness Ra can be selected based on the peak emission wavelength of a light source to optimize absorptivity near a target wavelength or wavelength range. The optical principles discussed herein can broadly be understood as one form of optical in-coupling to direct more light toward the LAM than could be accomplished with unstructured (e.g., substantially smooth) carrier structure components and surfaces. In comparison to an equivalent carrier structure with smooth surfaces, the carrier structure 110 with structured surface roughness at the boundary 113 can achieve the same absorptivity with up to approximately 45% less power.

Again with reference to FIG. 4, one method of making the carrier structure 110 involves providing the carrier body 112 with a roughened surface on at least one side, and subsequently coating the roughened surface with the LA layer 114. In situations where the carrier body 112 initially has smooth surfaces, there are many ways to roughen the surface, including mechanical abrasion such as grinding, lapping, milling, etc. Chemical means may also be employed to etch the surface of suitable materials. The roughness of the surface can be patterned or random depending on what roughening techniques are employed. The carrier body 112 can comprise a carrier substrate made of glass or another suitable material (e.g., which can be mechanically or chemically roughened), but it may comprise other materials such as dielectrics (e.g., ceramic) and/or polymer in one or more layers. For example, the carrier body 112 can comprise glass ceramic, such as sapphire and/or quartz. It may also include a semiconductor such as silicon, gallium arsenide, gallium nitride. It may also include a polymer such as a thermoset or a thermoplastic. Examples of thermosets are polyimide or epoxy. Examples of thermoplastics are PVC, PET, PEN, or PEI. It will be appreciated that the carrier body 112 can comprise one or more materials or material types, such as those discussed herein. If the carrier body 112 is made of a substance like glass, agents like hydrofluoric acid, glass etchant, or other chemicals may be used to actively roughen it. A combination of mechanical and chemical roughening may be used as well. Of course, a carrier body may have already-roughened surfaces (e.g., natural roughness resulting from substrate formation) with the desired roughness characteristics without a need for an active roughening stage. Any combination of such techniques for providing surface roughness can be used without departing from the scope of the present disclosure.

Referring still to FIG. 4, it is contemplated that the surface roughness of the carrier body 112 and LA layer 114 at the boundary 113 can exhibit fractal characteristics as a result of mechanical and/or chemical processes (as described above), which generally permits the average surface roughness Ra to be measured and verified readily with existing tools such as profilometers or scanners. However, it will be appreciated that more structured patterning or more random surface characteristics can be utilized without departing from the principles described herein. It will further be appreciated that localized surface roughness values can periodically exceed the average roughness value and that the variance of localized surface roughness values can also be controlled to be relatively small or relatively great.

As can further be seen in FIG. 4, the LA layer 114 can be deposited on a roughened surface of the carrier body 112 in a relatively thin coating. When the thickness of the LA layer 114 is generally in the same order of magnitude (or within a factor of 10) as the average surface roughness Ra of the surface of the carrier body 112 onto which the LA layer is deposited, the LA layer can maintain a relatively uniform thickness profile between its carrier-body-facing surface and its outer, non-carrier-body-facing (e.g., adhesive-facing) surface 115, which can result in similar surface roughness features and a similar average surface roughness Ra on both sides of the LA layer. For example, when the LA-layer-facing surface of the carrier body 112 has an average surface roughness Ra of approximately 50 nm and the LA layer 114 is deposited until the LA layer has an average thickness of approximately 30 nm, the resultant LA layer maintains an average surface roughness Ra of approximately 50 nm on both its carrier-facing surface (adjacent the boundary 113) and its outer surface 115. It will be appreciated that, due to the relatively uniform thickness of the LA layer 114, the shape of the outer LA layer surface 115 is generally similar to the shape of the LA-layer-facing surface of the carrier body onto which the LA layer is deposited along the boundary 113.

Having a relatively thin LA layer 114 with structured surface roughness on the outer surface 115 can result in TBDB efficiencies above and beyond the reflective properties at the boundary 113 discussed above. For example, in cases where the LA layer 114 has a thickness and an average surface roughness Ra approximately equal to, or more broadly, within an order of magnitude of one another (or within a factor of 10, e.g., a thickness of about 30 nm and an Ra of about 50 nm), it will be appreciated that the LAM can be formed with a relatively uniform thickness in conformity with the roughened surface features of the carrier body 112, which facilitates consistent light absorption and heat transfer across the LA layer regardless of any localized roughness (or relative absence thereof) at any particular location. This promotes more uniform heating of the LA layer 114 during the debonding process, which in turn enhances debonding efficiency and minimizes the need to increase the intensity of light emitted from the light source to ensure an adequate and efficient transfer of heat across all portions of the outer surface 115 to achieve sufficient thermal decomposition of an adhesive used for debonding (e.g., the adhesive 116 shown in FIGS. 7B-7C). By contrast, in regions where an LA layer is comparatively thick and/or has a comparatively high thermal mass, temperature increases due to light absorption are generally less than in the thinner regions, which can result in less efficient debonding where the thickness of the LAM exceeds a thickness needed for substantial absorption.

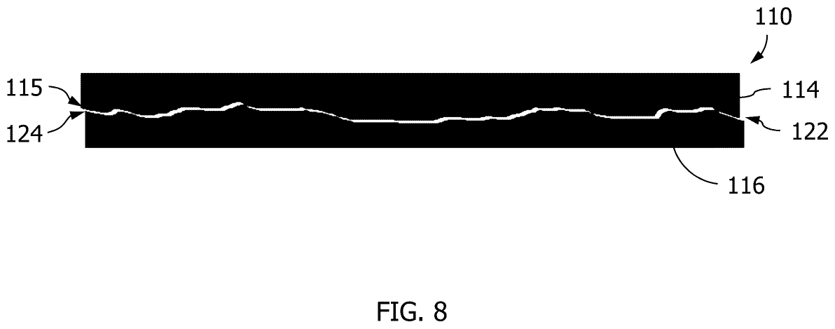

Additionally, when the LA layer outer surface 115 exhibits an average surface roughness between about 50 nm and about 5 microns (and, for preferred effectiveness, between about 100 nm and about 2 microns), a bonding strength between the LA layer 114 and adhesives (e.g., the adhesive 116 shown in FIGS. 7A-7B) is generally sufficient to withstand accidental or unwanted debonding while the carrier structure 110 carries an electronics structure, e.g., during general processing of electronics structures carried by the carrier structure. This contrasts surfaces that have a significantly greater average surface roughness (e.g., more than about 2 microns for some materials, and more broadly more than about 10 microns), as any further surface roughness can cause physical stress between the carrier structure and the electronics structures and can additionally weaken the bond strength of the adhesive. Accordingly, the surface roughness of carrier structures is generally tightly controlled to ensure adequate operation while electronics structures are being carried and processed prior to debonding. Notwithstanding the general desire to avoid roughness that causes an operational bonding strength of the adhesive to decrease, roughening the outer surface 115 in the range of about 50 nm to about 5 microns can cause selective bond weakening when the LA layer 114 is exposed to pulsed light from a light source (e.g., light source 130 shown in FIG. 7). In this situation, the surface roughness of the outer surface 115 provides a characteristically strong adhesive bonding strength for general processing before the debonding process is initiated, but the surface exhibits remarkable effectiveness in weakening the adhesive for debonding as soon as the debonding process is initiated. Moreover, as will be described in greater detail below in connection with FIG. 8, it will be appreciated that the roughened surface features of outer surface 115 (and vaporization or decomposition that occurs near these areas) can alleviate a stick-back phenomenon that can occur when an adhesive is debonded from a substantially flat carrier structure.

Now with reference to FIGS. 5 and 6, it will be appreciated that, in some cases, a user may use carrier structures where only one of the surfaces of the LA layer is roughened while the other surface is substantially smooth. FIG. 5 shows an illustrative example of a modified carrier structure 210 that includes an alternative LA layer 214 that is coated on a substantially smooth alternative carrier body 212 to define a relatively flat boundary 213 between the LA layer and the carrier body. On a non-carrier facing side of the LA layer 214, an outer surface 215 is roughened. FIG. 6 shows a second example of a modified carrier structure 310 that includes a second alternative carrier body 312 and a second alternative LA layer 314. In this embodiment, the carrier body 312 exhibits controlled surface roughness (e.g., between about 50 nm and about 5 microns) that defines a roughened boundary 313 between the carrier body and the LA layer 314. In this embodiment, the outer surface 315 is made smooth while the LA layer 314 is deposited or after the LA layer 314 is deposited. As should be apparent from the foregoing examples, it will be appreciated that in further embodiments, the average surface roughness Ra of each of these surfaces can be controlled independently (e.g., with two discrete average surface roughness coefficients Ra) without departing from the scope of the invention.

As with the carrier body 112, there are multiple methods that may be employed to roughen the LA layer 114, including mechanical abrasion such as grinding, lapping, milling, etc. Chemical means may also be employed to roughen the surface. Chemical and mechanical means may be employed together. Other means of roughening the surfaces may be radiative, such as a high-power laser. Additionally, plasma may be used to roughen the surface as well. Other means also include vacuum processes such as ion milling or reactive ion etching. Any combination of such means can be used without departing from the scope of the present disclosure.

Now referring to FIGS. 7A-7C, a method of using the carrier structure 110 with roughened outer surface 115 to temporarily carry an electronics structure 118 for processing will now be described. Referring to FIG. 7A, the electronics structure 118 is temporarily bonded to the carrier structure 110 by applying a temporary adhesive 116 between a bottom surface of the carrier structure 118 and the outer surface 115 of the LA layer 114, and then curing the adhesive 116 to form a temporarily bonded stack 120. In this embodiment, the LA layer 114 is roughened on both the carrier-body-facing side along boundary 113 and on the outer surface 115 which faces the adhesive. After the bonded stack 120 is formed, the electronics structure 118 can be processed (e.g., thinning, via formation, deposition, etc. As shown in FIG. 7B, a light source 130 (e.g., a broadband flashlamp) is pulsed to emit a debonding light (e.g., high-intensity beams of broadband light having wavelengths between about 200 nm to about 1.5 microns and a peak wavelength range between about 400 nm to about 600 nm). The emitted light is transmitted through the carrier body 112 toward the LA layer 114, and a substantial amount of the light is absorbed according to the above-described phenomena. With reference now to FIGS. 7B-7C, when a sufficient heat is transferred to portions of the adhesive 116 located near the outer surface 115 of the LA layer 114, this results in localized weakening of the bond strength of the adhesive, causing the electronics structure 118 to loosen from the carrier structure 110 so it can be separated.

As an example, the carrier structure 110 can include a glass carrier body 112 that is coated with an approximately 10% titanium-90% tungsten LA layer 114 with a thickness of approximately 200 nm. Before the LA layer 114 is applied, the carrier body 112 can be roughened (e.g., by chemical roughening) so that the surfaces of the carrier body 112 and the LA layer 114 at the boundary 113 demonstrate an average surface roughness Ra of around 500 nm. Due to the relative thinness of the LA layer 114, the carrier structure 110 exhibits a similar average surface roughness Ra of around 500 nm along outer surface 115 due to conformance of the LA layer to the roughness of the carrier body 112. In this example, it has been shown that broadband photonic debonding (e.g., a broad spectrum between about 200 nm and about 1.5 microns with a peak between about 400 nm and about 600 nm) can be achieved around 45% more effectively than debonding with a non-roughened carrier having otherwise similar components (e.g., according to the non-roughened carrier debonding described above in connection with FIGS. 2A-2B). More specifically, it has been shown that the radiant exposure needed to reliably debond a suitable adhesive 116 can be reduced from around 6.3 J/cm² (FIGS. 2A-2B) to around 3.4 J/cm² (FIGS. 7B-7C) to accomplish similar debonding effects.

The introduction of a roughened surface (e.g., the outer surface 115) at the interface between the carrier structure 110 and the adhesive 116 can alleviate a stick-back phenomenon that frequently occurs when carrier stacks have smooth debonding surfaces, especially when the weakening of the adhesive 116 creates a gaseous byproduct. A smooth interface (as opposed to a structured, roughened interface) creates a smooth manifold through which gaseous byproduct is expelled. This allows for a vacuum to form between the remaining adhesive and the carrier structure as residual gases cool, resulting in one example of stick-back. Stick-back can also be a consequence of excess energy transferred to the adhesive during debonding. In some cases during higher-temperature processing, heat can travel relatively deep into the adhesive before the debonding effects manifest, which can result in the expulsion of decomposition byproducts. Depending on the adhesive type, the decomposition byproducts can result in undesired tackification, solidification, or other forms of rebonding.

Referring additionally to FIG. 8, when the carrier structure 110 has structured roughness at the boundary with the adhesive 116 (e.g., the outer surface 115), a small manifold 122 forms where the adhesive separates from the carrier structure. While the separated structure previously fit (as a bonded stack), it is not possible to exactly match the resulting key-and-lock and/or contoured structures as they have changed shape and position. Because the boundaries of the manifold 122 are highly reticulated (as they are defined by the outer surface 115 and a surface 124 defined by remaining portions of the adhesive 116) and are not perfectly mating, there are very few large planar contact sites between the separated carrier structure 110 and adhesive 116. This inhibits the above-described stiction associated with comparatively flat surfaces, even under potential high-static fields that can occur as a result of debonding certain kinds of adhesives. The reticulated manifold 122 also tends to retain the gaseous byproduct that can evacuate more freely along smooth manifolds (as described above). It will be appreciated that the retention of gaseous byproduct can minimize and/or mitigate the formation of vacuums (e.g., as a result of the cooling that typically occurs after the adhesive 116 is thermally decomposed at a high temperature). Because the reticulated manifold 122 reduces forces between the carrier structure 110 and the loosened adhesive 116, less force is required to separate the processed electronics structure 118, particularly when upward force is applied from one side of the carrier structure 110 to an opposite side of the carrier structure in short succession (e.g., a peeling action) so that separation occurs in small segments across a length of the manifold.

After debonding, the carrier structure 110 and the processed electronics structure 118 are cleaned, and the carrier structure is reused again in another bond-debond cycle with a new electronics structure. There are a variety of techniques that can be used to clean including solvent, plasma, etc. A roughened adhesive-facing surface can lend itself more readily to ultrasonic cleaning because the contours in the surface provide numerous (e.g., thousands or tens of thousands of) cavitation sites during cleaning. This increases the rate at which cleaning can be performed and thus reduces the cost of the cleaning process.

In some circumstances, roughening both surfaces of the LA layer (as generally discussed above in connection with FIGS. 4 and 7A-7C) may yield the most efficient debonding results in accordance with the principles discussed herein. In other words, roughening the carrier-body-facing side can aid in increasing the absorption of the light from the light source, thereby heating the LAM more readily. Further, roughening the adhesive-facing side of the LA layer can aid in releasing the adhesive and in cleaning. Of course, additional considerations may inform a more selective structuring on only one side of the LA layer (e.g., FIGS. 5, 6) or over only a portion of the carrier structure. Similarly, additional considerations may inform a user to select different roughness parameters for different regions (e.g., to improve effectiveness with different light wavelengths).

In sum, the surface roughness of the carrier-body-facing side of the LA layer is not necessarily the same as it is on the adhesive-facing side and may be independently controlled.

In some cases, the type of adhesive used for forming the temporary bonded stack can affect the desired range of average surface roughness values for more efficient debonding. For example, when using the above-identified broadband flashlamp (with light wavelengths between about 200 nm and about 1,500 nm) and applying a 200 nm-thick titanium-tungsten LA layer to the roughened glass carrier body, it has been found that the most efficient debonding occurs for a laminated tape adhesive when the average surface roughness Ra of the carrier body (and both sides of the LA layer) is maintained between about 60 nm and about 400 nm. Likewise, it has been found that the most efficient debonding occurs for a liquid thermoset adhesive when the average surface roughness Ra of the carrier body (and both sides of the LA layer) is maintained between about 400 nm and about 5 microns.

Moreover, in some cases, LA layers like the above-described LA layer 114 may not be included in a roughened carrier structure at all, such as in cases where the adhesive is directly heated by incident light and the light absorptivity of the adhesive can be enhanced simply by roughening the carrier body for increased exposure at the surface level. Accordingly, although the above-described carrier structures include a carrier body with a LA layer carried by the carrier body, it will be appreciated that the terms “carrier” or “carrier structure” as used herein can include carriers with or without a LA layer.

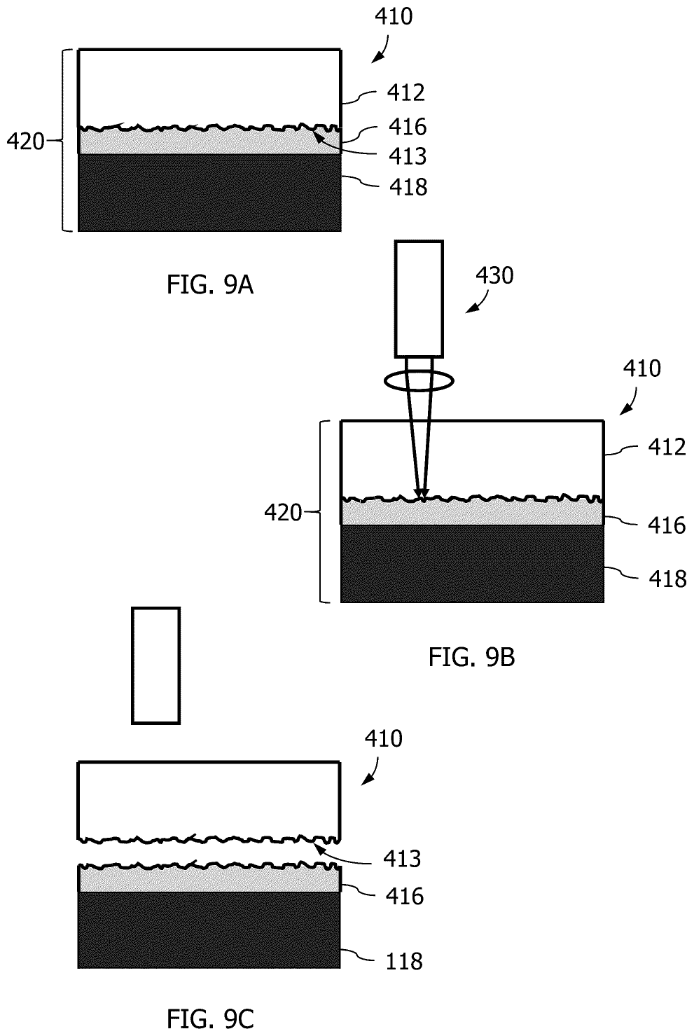

In cases where light is used to debond an adhesive directly carried by the carrier body (e.g., without the presence of a LA layer) a carrier structure with one or more roughened surfaces may be adhesively bonded directly to an electronics structure. In some such examples, the adhesive may itself be light-absorbing and/or include an additive of light-absorbing material. Similar to the roughened boundary 113 between the carrier body 112 and LA layer 114 described above, a roughened carrier-adhesive boundary (without a LA layer) can enable enhanced heat transfer directly at the carrier-adhesive boundary, e.g., when the adhesive has sufficient light-absorbing and thermal decomposition characteristics to provide both functions, while also achieving the advantages related to stick-back as discussed above. Now with reference to FIGS. 9A-9C, an alternative carrier structure 410 and a method of using the alternative carrier structure 410 to temporarily carry an electronics structure 418 for processing will now be described. The alternative carrier structure 410 includes a carrier body 412 with a roughened bonding surface 413, but no light-absorbing layer. Referring to FIG. 9A, the electronics structure 418 is temporarily bonded to the carrier structure 410 by applying a temporary adhesive 416 between a bottom surface of the electronics structure 418 and the bonding surface 413 of the carrier (e.g., carrier body 412), and then curing the adhesive 416 to form a temporarily bonded stack 420. After the bonded stack 420 is formed, the electronics structure 418 can be processed (e.g., thinning, via formation, deposition, etc.). As shown in FIG. 9B, a laser light source 430 (e.g., a laser that emits NIR light having a wavelength of 1,500 nm) is pulsed to emit a debonding light. The laser beam may be augmented by a beam spreader to increase the width of the beam for faster processing by shortening the time needed to scan the entire surface area of the bonded stack. The emitted light is transmitted through the carrier body 412 toward the adhesive 416, and a substantial amount of the light is absorbed according to the above-described phenomena. With reference now to FIGS. 9B-9C, when a sufficient heat is transferred to portions of the adhesive 416 located near the bonding surface 413, this results in localized weakening of the adhesive, causing the electronics structure 418 to loosen from the carrier structure 410 so it can be separated.

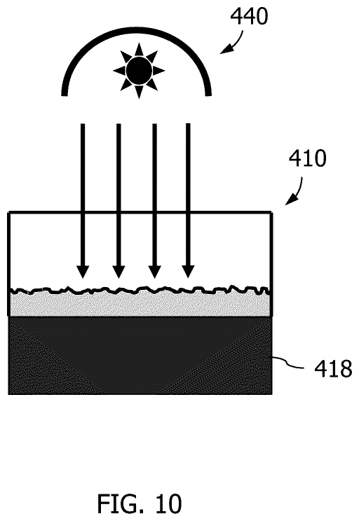

Now referring to FIG. 10, in a substantially similar process, the alternative carrier structure 410 without an LA layer can be used with a broadband flashlamp 440 to debond the electronics structure 418 via photonic debonding.

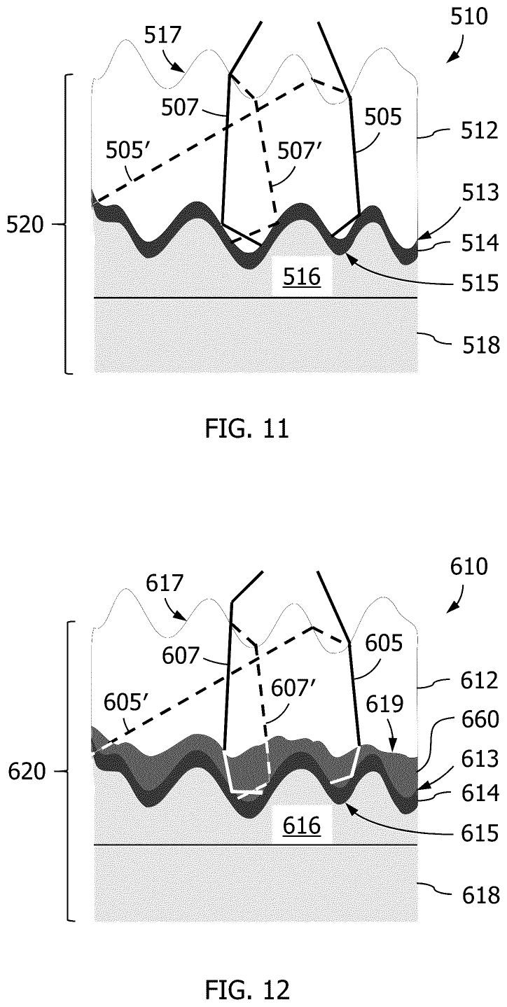

Now with reference to FIG. 11, an alternative carrier structure 510 with additional roughness is shown in accordance with another alternative embodiment. Here, the carrier structure 510 includes a carrier body 512 and a LA layer 514 that define a roughened boundary 513 and a roughened outer surface 515, which are generally the same as the corresponding features discussed above in connection with the carrier structure 110. Also similar to the above-described carrier structure 110, the carrier structure 510 is temporarily bonded to an electronics structure 518 to define a bonded stack 520. Notably, the carrier (e.g., carrier body 512) includes a roughened light-facing surface 517 (broadly, a non-adhesive-facing surface) located opposite the roughened surface along the boundary 513. Providing a roughened surface structure on this side of the carrier can further enhance the above-described in-coupling principles by causing additional light manipulation at this boundary to direct even more light toward the LA layer 514. It is contemplated that the roughened structure on this side of the carrier ideally has an average surface roughness Ra of between approximately 50 nm and approximately 10 microns.

As shown in FIG. 11, several example incident light rays 505, 507 and reflected components 505′, 507′ are shown to indicate reflection and refraction paths of incident light rays coming from an incoherent light source.

It will be appreciated that the Ra of the light-facing surface 517 can be tightly controlled (e.g., relative to the wavelength of light generated by the light source) to achieve in-coupling similar to the light-manipulating phenomena described above in connection with roughened surfaces on the other side of the carrier. In other words, providing a structured surface on the light-source-facing side of the carrier can also increase the amount of incident light that is directed toward the LA layer 514 rather than being reflected back toward the light source. This phenomenon can be especially strong when the Ra of this surface is less than or approximately equal to the wavelength of the light used for the debonding process.

Of course, as is further shown in FIG. 11, it is contemplated that both the upper and lower surfaces of the carrier body 512 can be structured with roughened surfaces. Although the embodiment shown in FIG. 11 depicts the top and bottom surfaces of the carrier body 512 having a similar Ra, in some circumstances, it may be beneficial to control the surface roughness parameters of each side independently according to different considerations. For example, the Ra of each side could be controlled independently to enhance light absorption at multiple wavelengths, to accommodate for other manufacturing considerations, and/or to facilitate other processes related to debonding reusing the carrier structure.

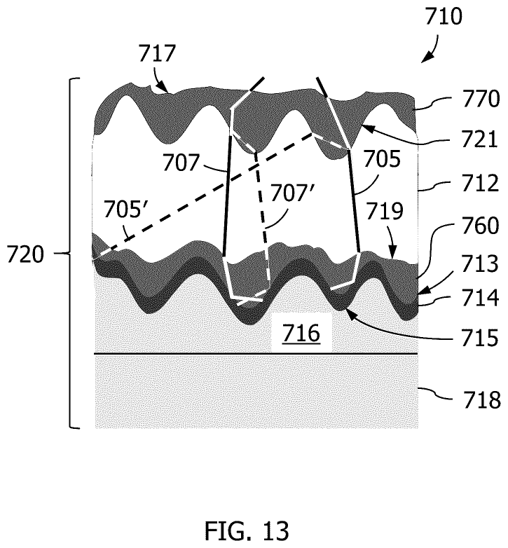

Now with reference to FIGS. 12 and 13, further alternative carrier structures 610 (FIGS. 12) and 710 (FIG. 13) are shown with one or more supplemental layers (e.g., light-manipulating layers, light-refractive layers, and/or interlayers), which may define additional roughened boundaries in accordance with further alternative embodiments. Referring specifically to FIG. 12, the carrier structure 610 includes a carrier body 612. The carrier body 612 has a roughened light-facing surface 617. A supplemental layer 660 is interposed between the carrier body 612 and a roughened LA layer 614. The supplemental layer 660 has opposing roughened surfaces to define two roughened boundaries: a first (lower) roughened boundary 613 between the supplemental layer and the LA layer 614, and a second (upper) roughened boundary 619 between the supplemental layer and the carrier body 612. An adhesive 616 is used to temporarily bond the carrier structure 610 to an electronics structure 618 to define a bonded stack 620.

Referring to FIG. 13, the carrier structure 710 includes a carrier body 712. A first (lower) supplemental layer 760 is interposed between the carrier body 712 and a roughened LA layer 714. The first supplemental layer 760 has opposing roughened surfaces to define two roughened boundaries: a first (lower) roughened boundary 713 between the supplemental layer and the LA layer 714, and a second (upper) roughened boundary 719 between the supplemental layer and the carrier body 712. A second (upper) supplemental layer 770 is bonded to (broadly, carried by) the carrier body 712 opposite the first supplemental layer 760. The second supplemental layer 770 includes a roughened light-facing surface 717 and a second roughened surface opposite the light-facing surface that defines a roughened boundary 721 between the second supplemental layer and the carrier body 712. An adhesive 716 is used to temporarily bond the carrier structure 710 to an electronics structure 718 to define a bonded stack 720.

The structured supplemental layers 660, 760, and 770 can be made of the same, similar, and/or different materials than the respective carrier bodies (612, 712), LA layers (614, 714), and adhesives (618, 718) discussed above. The addition of structured supplemental layers can be used to provide further enhancement in accordance with the principles discussed herein (e.g., by manipulating more light), or the supplemental layers can be provided as functional extensions of the carrier body to alleviate manufacturing or durability concerns with the above-described embodiments. As non-limiting examples, supplemental layer materials can be used to balance surface stress, to provide an improved fracture modulus near sensitive boundaries, to reduce bow warpage, or to induce additional light scattering. Thus, an supplemental layer could be selected to provide a particular characteristic such as a CTE or an index of refraction that is different from the carrier body itself. Of course, some supplemental layers could additionally include light-absorptive substances and at least partially serve a function of an LAM as described herein. Similar to the phenomena described above in connection with FIG. 11, exemplary incident light rays 605, 607 and reflected components 605′, 607′ are shown in FIG. 12 to indicate reflection and refraction paths of incident light rays coming from an incoherent light source. Likewise, exemplary incident light rays 705, 707 and reflected components 705′, 707′ are shown in FIG. 13 to indicate reflection and refraction paths of incident light rays coming from an incoherent light source. It will be appreciated that the addition of one or more supplemental layers in the carrier structures can be used to provide additional structured roughening to control the ingress of light at one or more wavelengths to provide additional energy and heat efficiency during operation.

As broad examples of the practical advantages to carrier structures with one or more roughened surfaces in accordance with the above-described examples, it will be appreciated that the efficiencies provided by the optical in-coupling and effective heat transfer principles described herein can result in a reduction in a maximum light intensity required of light sources to cause debonding in the adhesive. This can substantially reduce power loads on the light source and/or in optical focusing equipment, resulting in extended equipment lifetimes. Alternatively, the roughening may allow beams to be expanded to expose a larger area (e.g., by providing a longer lamp head for photonic debonding or a beam-expanded laser). This reduces the number of pulses required of a light source to debond a carrier wafer that has a given contact area. For example, in some embodiments, a flash lamp could be long enough to extend across the entire length or diameter of the wafers being processed, which can greatly simplify the debonding process by converting complex, two-dimensional irradiation sequences into streamlined, one-dimensional sequences. Additionally, the increased beam size can decrease the falloff rate of power intensity at beam edges. The decreased falloff rate at the edges can reduce thermal gradients induced in the processed electronics structure during the debonding process. Reduced thermal gradients can minimize thermal stress in the electronics structure and/or in the carrier structure during debonding, which can result in an increased yield in undamaged electronics structures and increased durability and reusability of the carrier structures. When using a laser, the debonding can be achieved faster with a beam-expanded laser since more area can be covered by each laser pulse.

It has been determined that careful control over the morphology of roughened surfaces in a carrier structure can improve the life cycle of the carrier structure by a factor of 10. Additionally, as discussed above, the roughening of the carrier structure can generally aid in releasing the adhesive bond between the carrier and the adhesive during debonding.

The average surface roughness Ra of the roughened carrier surfaces described herein may be in a range from about 50 nm to about 5 microns and more desirably between about 100 nm to about 2 microns. When broadband light is used, the average surface roughness Ra may be approximately equal to the peak wavelength of the broadband light, e.g., between about 400 nm and about 600 nm. The average surface roughness Ra of each surface can be measured using a variety of techniques including a contact profilometer or an optical profilometer. Alternatively, Ra can be measured using a scanning electron microscope (SEM).

In embodiments where the carrier structure includes a LA layer, the LA layer may have a thickness of between about 30 nm and about 5 microns. In particular embodiments, the thickness of the LA layer may be between about 50 nm and about 300 nm. The thickness of the LA layer may be approximately on the order of the average surface roughness Ra of an adjoining carrier body surface or slightly thinner than this roughness characteristic.

As described herein, electronics structures (e.g., electronics devices) for use with the carrier structures described herein can comprise semiconductor wafers and/or may comprise any variety of substrates or other electronics-related materials including glass, metal, ceramic, and/or polymers.

In an example method of using a carrier structure as disclosed herein having a roughened bonding face or surface (opposite the light-receiving face or surface) for engaging the adhesive between the carrier structure and the electronics structure, the adhesive may be applied to the roughened bonding face or surface in a way such that the adhesive does not completely “wet” the roughened bonding face or surface. The adhesive does not fill all recesses in the roughened surface such that voids are left between the adhesive and the bonding face due to the roughening, and the voids remain when the adhesive is cured to temporarily bond the electronics structure to the carrier body. The bond strength of the adhesive is sufficient to securely hold the electronics structure to the carrier structure but results in overall less bonded surface area of adhesive in engagement with the carrier structure than if the carrier structure were not roughened. It will be appreciated the bonding face of the carrier structure can be formed by the LA layer (if present) or the carrier body, etc. When the bonded stack is irradiated from the carrier side to debond the electronics structure, light transmitted through the carrier body (e.g., absorbed by the LA layer) results in heating of the voids between the roughened surface and the adhesive, which facilitates loosening of the bond and permits removal of the electronics structure from the carrier structure.

In one example, a bonded stack (including carrier structure and electronics structure), such as any of those disclosed herein, may have a total thickness of about 1 mm or less. Such bonded stack can include a carrier body (with or without supplemental layers) having a thickness of about 800 microns, an LA layer having a thickness of about 0.2 microns or less, an adhesive layer having a thickness of about 25 microns or less, and an electronics structure (e.g., wafer) having a thickness of about 25-50 microns or less. These values are provided by way of example without limitation.

In one aspect of the present disclosure, roughening of the present disclosure (e.g., carrier body and/or LA layer) permits a wider flashlamp or laser debonding beam width (e.g., beam area of at least 10 cm², more desirably 20 cm², more desirably 30 cm², more desirably 40 cm², more desirably 50 cm², more desirably 60 cm², more desirably 70 cm², more desirably 80 cm², more desirably 90 cm², more desirably 100 cm², more desirably 110 cm², more desirably 120 cm², more desirably 130 cm², and even more desirably 140 cm²) to be used to heat a broad area (e.g., beam area) of the bonded stack at the same time at less power per surface area of illumination. For example, larger (e.g., longer) flashlamp bulbs can be used for photonic debonding. Moreover, expanded beam lasers can be used, which can be expanded beyond typical expanded laser beams. For example, an expanded laser light beam can be used that desirably has a beam width of at least about 3 mm, more desirably about 5 mm, more desirably about 8 mm, more desirably about 10 mm (e.g., beam area of at least 1 cm²), even more desirably about 15 mm (e.g., beam area of at least 2.25 cm²), and even more desirably about 20 mm (e.g., beam area of at least 4 cm²). The beam width can be expressed as a ratio with respect to the thickness of the bonded stack. In the example immediately above, the bonded stack has a thickness of about 1 mm, such that the corresponding ratios (mm: mm) would be at least about 3:1, more desirably about 5:1, more desirably about 8:1, more desirably about 10:1, even more desirably about 15:1, and even more desirably about 20:1. The use of roughening of the present disclosure permits such broader beam widths, which increase the speed needed to irradiate the entire surface area of a bonded stack, increase yield because of reduction of damage to the electronics structures, and permit the carrier structures to be reusable.

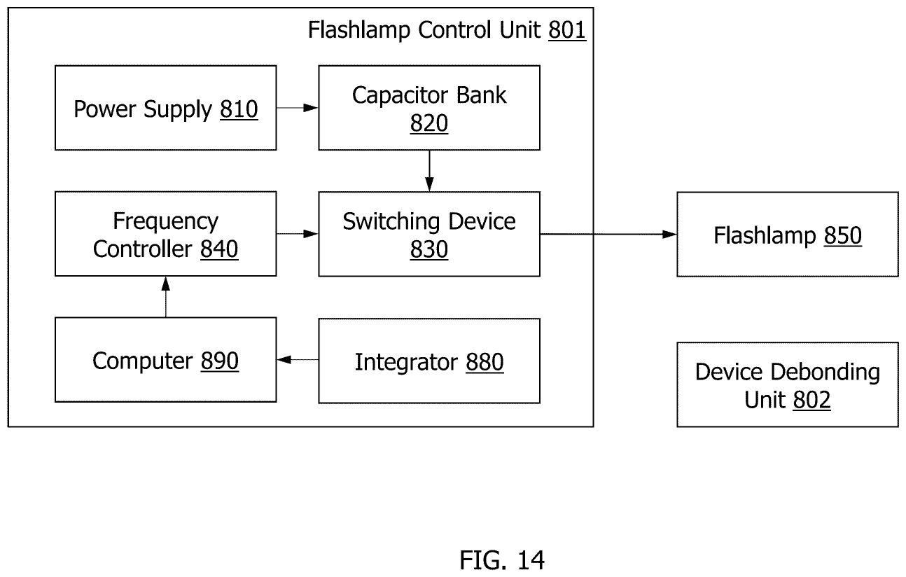

Although it is contemplated that the carrier structures described herein are suitable for use in a variety of systems suitable for temporary bonding and debonding, provided in FIG. 14 is a block diagram demonstrating one example of a photonic debonding system 800 (broadly, “heating system” for heating bonded stack) that can be used for photonic debonding as with any carrier structure disclosed herein, such as with, e.g., the carrier structure 110 and the electronics structure 118. As shown, the photonic debonding system 800 includes a flashlamp control unit 801 and device debonding unit 802. Flashlamp control unit 801 includes a capacitor-bank-charging power supply 810, a capacitor bank 820, an insulated gate barrier transistor (IGBT)-based switching device 830, a frequency controller 840, and a computer 890. Computer 890 includes a processor and various storage devices (non-transitory tangible storage medium(s)) storing processor-executable instructions for operating the system according to the present disclosure. The capacitors in capacitor bank 820 are, for example, electrolytic capacitors. Capacitor bank 820 may alternatively be switched with a silicon-controlled rectifier (SCR) switching device with an inductor placed in series to control the pulse length of emitted light.

Capacitor bank 820 can be charged by capacitor-bank-charging power supply 810. Charges from capacitor bank 820 are then discharged into flashlamp 850 via IGBT-based switching device 830 while IGBT-based switching device 830 is being switched on-and-off repeatedly by frequency controller 840 during the discharge. Frequency controller 840 controls the gating of IGBT-based switching device 830 that, in turn, controls the switching frequency of the discharge. The repeated on-and-off switching of IGBT-based switching device 830 is intended to modulate the current flow from capacitor bank 820 to flashlamp(s) 850, which in turn switches flashlamp(s) 850 on and off. In other words, the frequency or pulse length of light pulses emitted by flashlamp(s) 850 is dictated by frequency controller 840. Each time the flashlamp(s) are turned on, a broad area (e.g., corresponding to beam areas discussed above) is irradiated and thus heated at the same time. Further details about calibrating and operating a photonic debonding system such as the system 800 are provided in U.S. Pat. No. 11,996,384, which is hereby incorporated herein by reference in its entirety.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the present disclosure are achieved and other advantageous results attained.

As various changes could be made in the above constructions and methods without departing from the scope of the present disclosure, it is intended that all matter contained in the above description and shown in the accompanying drawings shall be interpreted as illustrative and not in a limiting sense.

### OTHER STATEMENTS OF THE DISCLOSURE

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above.

A1. A carrier structure for temporarily carrying an electronics structure to be debonded from the carrier structure, the carrier structure comprising:

an electronics structure carrier, the electronics structure carrier comprising a first face and a second face located generally opposite the first face, the second face comprising a roughened surface, an average surface roughness of the roughened surface of the second face being between about 50 nm and about 5 microns.

A2. The carrier structure of statement A1, wherein the electronics structure carrier comprises a carrier body and a light-absorbing layer carried by the carrier body, the carrier body including a first carrier body surface and a second carrier body surface, the light-absorbing layer including a first light-absorbing layer surface and a second-light-absorbing layer surface:
wherein the light-absorbing layer is configured to absorb light transmitted through the first face of the electronics structure carrier toward the first light-absorbing layer surface to generate heat;
wherein the light-absorbing layer is further configured to transfer generated heat through the second light-absorbing layer surface;
wherein the second light-absorbing layer surface defines the second face; and wherein the second carrier body surface and the first light-absorbing layer surface are disposed between the first face and the second face.

A3. The carrier structure of statement A2, wherein the second carrier body surface is generally coincident with the first light-absorbing layer surface.

A4. The carrier structure of statement A3, wherein an average surface roughness of the second carrier body surface is between about 50 nm and about 5 microns.

A5. The carrier structure of statement A3, wherein an average surface roughness of the first light-absorbing layer surface is approximately equal to an average surface roughness of the roughened surface of the second face.

A6. The carrier structure of statement A5, wherein the average surface roughness of the first light-absorbing layer surface is less than about 10 nm.

A7. The carrier structure of statement A2, wherein the light-absorbing layer has an average thickness equal to an average distance between the first light-absorbing layer surface and the second light-absorbing layer surface, wherein the average thickness of the light-absorbing layer is between about 30 nm and about 5 microns.

A8. The carrier structure of statement A2, the carrier further comprising a supplemental layer carried by the carrier body, the supplemental layer having a different index of refraction than an index of refraction of the carrier body; wherein the supplemental layer comprises a first supplemental layer surface having an average surface roughness between about 50 nm and about 5 microns.

A9. The carrier structure of statement A8, wherein the supplemental layer is carried by the carrier body with the first supplemental layer surface engaging the carrier body.

A10. The carrier structure of statement A9, wherein the supplemental layer is disposed between the carrier body and the light-absorbing layer, the first supplemental layer surface being generally coincident with the second carrier body surface, and the supplemental layer comprising a second supplemental layer surface located generally opposite the first supplemental layer surface, the second supplemental layer surface being generally coincident with the first light-absorbing layer surface.

A11. The carrier structure of statement A10, wherein an average surface roughness of the second supplemental layer surface is less than about 10 nm.

A12. A method of producing an electronics structure carrier for temporarily carrying an electronics structure to be debonded from the electronics structure carrier, the method comprising:
providing a carrier body defining a non-roughened surface, the non-roughened surface having an average surface roughness below about 10 nm;
forming a light-absorbing layer on the non-roughened surface, the light-absorbing layer comprising a carrier-body-facing surface and a bonding surface located opposite the carrier-body-facing surface, the bonding surface having a surface roughness between about 50 nm and about 5 microns.

A13. A method of using an electronics structure carrier with one or more roughened surfaces to temporarily carry an electronics structure for processing, the method comprising:
forming a temporary stack comprising the electronics structure carrier, a first electronics structure to be processed, and a temporary adhesive, wherein the electronics structure carrier comprises a first roughened surface, the first roughened surface having an average surface roughness between about 50 nm and about 5 microns, and wherein the temporary adhesive is disposed between the first roughened surface and the first electronics structure to be processed;
processing the electronics device while the electronics device is temporarily bonded to the carrier structure;
emitting one or more pulses of light from a light source such that the light is transmitted through a carrier body of the electronics carrier structure toward the roughened surface to generate heat to cause at least a portion of the temporary adhesive to weaken adhesively, the one or more pulses of light emitted from the light source having a beam area of at least 10 cm²; and separating the processed electronics device from the carrier structure.

A14. The method of statement A13, wherein the emitting one or more pulses of light from the light source occurs in a first horizontal position relative to the electronics structure carrier, the method further comprising, subsequent to the emitting one or more pulses of light from the light source in the first horizontal position, emitting one or more pulses of light from the light source in a second position relative to the electronics structure carrier, the second position being spaced horizontally from the first position by approximately a beam width of the light emitted by the light source.

A15. A method of producing an electronics structure carrier for temporarily carrying an electronics structure to be debonded from the electronics structure carrier, the method comprising:
providing a carrier body defining a roughened surface;
forming a light-absorbing layer on the non-roughened surface, the light-absorbing layer comprising a carrier-body-facing surface and a bonding surface located opposite the carrier-body-facing surface, the light-absorbing layer conforming to the roughened surface of the carrier body to cause the bonding surface to have a surface roughness between about 50 nm and about 5 microns.

A16. A method of using an electronics structure carrier with one or more roughened surfaces to temporarily carry an electronics structure for processing, the method comprising:
forming a temporary stack comprising the electronics structure carrier, a first electronics structure to be processed, and a temporary adhesive, wherein the electronics structure carrier comprises a first roughened surface, the first roughened surface having an average surface roughness between about 50 nm and about 5 microns, and wherein the temporary adhesive is disposed between the first roughened surface and the first electronics structure to be processed;
processing the electronics device while the electronics device is temporarily bonded to the carrier structure;
heating an area of at least 10 cm² of the bonded stack at the same time to cause at least a portion of the temporary adhesive to weaken adhesively; and
separating the processed electronics device from the carrier structure.

A17. A debonding system for debonding an electronics structure from a carrier structure, the debonding system comprising:
an electronics structure carrier for temporarily carrying an electronics structure, the electronics structure carrier comprising a bonding surface configured to be adhered via a temporary adhesive to the electronics structure for temporarily carrying the electronics structure, the bonding surface having an average surface roughness between about 50 nm and about 5 microns; and a heating system configured to heat an area of at least 10 cm² of the electronics structure carrier at the same time to cause at least a portion of the temporary adhesive to weaken adhesively.

A18. A method of using an electronics structure carrier with one or more roughened surfaces to temporarily carry an electronics structure for processing, the method comprising:
forming a temporary stack comprising the electronics structure carrier, a first electronics structure to be processed, and a temporary adhesive, wherein the electronics structure carrier comprises a first roughened surface, the first roughened surface having an average surface roughness between about 50 nm and about 5 microns, and wherein the temporary adhesive is disposed between the first roughened surface and the first electronics structure to be processed;
wherein the adhesive and the first roughened surface define a plurality of voids therebetween;
processing the electronics device while the electronics device is temporarily bonded to the carrier structure;
heating an area of the bonded stack to heat the plurality of voids and cause at least a portion of the temporary adhesive to weaken adhesively; and
separating the processed electronics device from the carrier structure.

What is claimed is:

1. A reusable carrier structure for temporarily carrying electronics structures to be debonded from the carrier structure by flashlamp illumination in photonic debonding, the reusable carrier structure comprising:
an electronics structure carrier configured to temporarily carry the electronics structures in multiple temporary bond-debond use cycles of the electronics structure carrier, the electronics structure carrier comprising a first light-receiving face and a second face, the light-receiving face being configured for receiving light from the flashlamp illumination, the second face being located generally opposite the first light-receiving face, the second face comprising a roughened surface, the electronics structure carrier comprising a carrier body configured to permit transmission of light from the flashlamp illumination via the first light-receiving face to pass through the carrier body toward the second face, the roughened surface of the second face having an average surface roughness between about 50 nm and about 5 microns to facilitate photonic debonding of the electronics structures from the electronics structure carrier.

2. The reusable carrier structure of claim 1, wherein the carrier body defines the second face comprising the roughened surface.

3. The reusable carrier structure of claim 2, wherein the electronics structure carrier further comprises a light-absorbing layer carried by the carrier body and located with respect to the carrier body to be irradiated by light transmitted through the carrier body from the flashlamp illumination, the light-absorbing layer comprising a first light-absorbing layer surface facing toward the roughened surface of the second face and a second light-absorbing layer surface facing away from the roughened surface of the second face, the light-absorbing layer being configured to absorb light transmitted through the carrier body to generate heat, the light-absorbing layer being configured to transfer generated heat through the second light-absorbing layer surface to facilitate photonic debonding of the electronics structures from the electronics structure carrier.

4. The reusable carrier structure of claim 3, wherein the light-absorbing layer comprises a thermally stable material for absorbing high-intensity photonic debonding light pulses in multiple temporary bond-debond use cycles of the electronics structure carrier.

5. The reusable carrier structure of claim 3, wherein the light-absorbing layer has an average layer thickness on the same order of magnitude as the average surface roughness of the second carrier body surface.

6. The reusable carrier structure of claim 5, wherein the light-absorbing layer has an average layer thickness of between about 30 nm and about 5 microns.

7. The reusable carrier structure of claim 5, wherein the second light-absorbing layer surface is roughened due to conformance of the light-absorbing layer to the roughened surface of the second face.

8. The reusable carrier structure of claim 3, wherein the second light-absorbing layer surface is roughened.

9. The reusable carrier structure of claim 8, wherein the second light-absorbing layer surface has an average surface roughness between about 50 nm and about 5 microns.

10. The reusable carrier structure of claim 2, further comprising a supplemental layer carried by the carrier body, the supplemental layer having a different index of refraction than an index of refraction of the carrier body to modify transmission of light from the flashlamp illumination to the light-absorbing layer.

11. The reusable carrier structure of claim 10, wherein the supplemental layer comprises a first surface having an average surface roughness between about 50 nm and about 5 microns.

12. The reusable carrier structure of claim 10, wherein the supplemental layer engages the carrier body.

13. The reusable carrier structure of claim 1, wherein the first light-receiving face comprises a roughened surface, and wherein an average surface roughness of the roughened surface of the first light-receiving face is between about 50 nm and about 5 microns.

14. The reusable carrier structure of claim 13, wherein the average surface roughness of the first light-receiving face is configured to augment incident light having a first peak emission wavelength, and the average surface roughness of the second face is configured to augment incident light having a second peak emission wavelength different from the first peak emission wavelength.

15. The reusable carrier structure of claim 1, wherein the electronics structure carrier further comprises a light-absorbing layer carried by the carrier body and located with respect to the carrier body to be irradiated by light transmitted through the carrier body from the flashlamp illumination, the light-absorbing layer comprising a first light-absorbing layer surface facing toward the carrier body for being irradiated by light transmitted through the carrier body and comprising a second light-absorbing layer surface facing away from the carrier body, the light-absorbing layer being configured to absorb light transmitted through the carrier body to generate heat, the light-absorbing layer being configured to transfer generated heat through the second light-absorbing layer surface to facilitate photonic debonding of the electronics structures from the electronics structure carrier, the second light-absorbing layer surface defining the roughened surface of the second face.

16. The reusable carrier structure of claim 15, wherein the light-absorbing layer engages the second carrier body surface.

17. The reusable carrier structure of claim 16, wherein an average surface roughness of the second carrier body surface is between about 50 nm and about 5 microns.

18. The reusable carrier structure of claim 16, wherein an average surface roughness of the first light-absorbing layer surface is approximately equal to the average surface roughness of the roughened surface of the second face.

19. The reusable carrier structure of claim 16, wherein an average surface roughness of the first light-absorbing layer surface is less than about 10 nm.

20. The reusable carrier structure of claim 15, wherein the light-absorbing layer has an average thickness equal to an average distance between the first light-absorbing layer surface and the second light-absorbing layer surface, the average thickness of the light-absorbing layer being between about 30 nm and about 5 microns.

21. The reusable carrier structure of claim 15, wherein the carrier further comprises a supplemental layer carried by the carrier body, the supplemental layer having a different index of refraction than an index of refraction of the carrier body to augment transmission of light from the flashlamp illumination to the light-absorbing layer.

22. The reusable carrier structure of claim 21, wherein the supplemental layer comprises a first supplemental layer surface having an average surface roughness between about 50 nm and about 5 microns.

23. The reusable carrier structure of claim 22, wherein the supplemental layer engages the carrier body.

24. The reusable carrier structure of claim 23, wherein the supplemental layer is disposed between the carrier body and the light-absorbing layer, the first supplemental layer surface engaging the second carrier body surface, the supplemental layer comprising a second supplemental layer surface located opposite the first supplemental layer surface, the second supplemental layer surface engaging the first light-absorbing layer surface.

25. The reusable carrier structure of claim 22, wherein an average surface roughness of the second supplemental layer surface is less than about 10 nm.

26. The reusable carrier structure of claim 1, wherein the average surface roughness of the roughened second surface of the second face is between about 60 nm and about 400 nm.

27. The reusable carrier structure of claim 1, wherein the average surface roughness of the roughened second surface of the second face is between about 400 nm and about 5 microns.

28. A photonic debonding system comprising a stack and a light source, the stack comprising the reusable carrier structure of claim 1 and an electronics structure temporarily bonded thereto;
wherein the light source is configured to generate the flashlamp illumination with an intensity sufficient to debond the electronics structure from the carrier; and
wherein an average surface roughness of the roughened surface of the second face is about equal to a peak emission wavelength of the light source or less than the peak emission wavelength of the light source within an order of magnitude.

29. A method of producing a carrier structure for temporarily carrying an electronics structure to be debonded from the carrier structure by photonic debonding, the method comprising:
providing a roughened surface on a carrier body, the roughened surface having an average surface roughness between about 50 nm and about 5 microns; and
placing a light-absorbing layer on the carrier body, the light-absorbing layer comprising a carrier-body-facing surface and a bonding surface located opposite the carrier-body-facing surface, the bonding surface having a surface roughness between about 50 nm and about 5 microns.

30. The method of claim 29, wherein the light-absorbing layer has an average thickness less than or approximately equal to the average surface roughness of the roughened surface of the carrier body.

31. The method of claim 30, wherein the light-absorbing layer applied to the carrier body to cause the light-absorbing layer to conform to the roughened surface of the carrier body to cause the bonding surface of the light-absorbing layer to be roughened.

32. A method of using a carrier structure having one or more roughened surfaces for processing electronics structures, the method comprising:
forming a temporary stack comprising the carrier structure, a first electronics structure to be processed, and a temporary adhesive disposed between the carrier structure and the first electronics structure, wherein the carrier structure comprises a roughened surface having an average surface roughness between about 50 nm and about 5 microns, the roughened surface of the carrier structure facing toward the temporary adhesive;
processing the electronics structure while the electronics structure is temporarily bonded to the carrier structure;
emitting one or more pulses of light from a light source such that the light is transmitted into the carrier structure toward the roughened surface to generate heat at a boundary between the carrier structure and the temporary adhesive to loosen the electronics structure with respect to the carrier structure; and
separating the processed electronics structure from the carrier structure.

33. The method of claim 32, wherein the carrier structure comprises a carrier body and a light-absorbing layer carried by the carrier body, and wherein the temporary adhesive engages the light-absorbing layer to form the temporary stack.

34. The method of claim 32, wherein emitting one or more pulses of light from a light source comprises emitting pulses of incoherent light from a flashlamp, a peak wavelength range of the light pulsed from the flashlamp being on the order of the average surface roughness of the roughened surface.

35. The method of claim 34, wherein the light source is an incoherent light source, and wherein the peak wavelength range is between about 400 nm and about 600 nm.

36. The method of claim 32, wherein the adhesive comprises a laminated tape, and wherein the average surface roughness of the roughened surface is between about 60 nm and about 400 nm.

37. The method of claim 32, wherein the adhesive comprises a liquid thermoset adhesive and the average surface roughness of the roughened surface is between about 400 nm and about 5 microns.
